(19) United States
(12) Patent Application Publication
(10) Pub. No.: US 2009/0277662 A1
(43) Pub. Date: Nov. 12, 2009

(54) ELECTRICAL DEVICE, BAND STRUCTURE AND METHODS FOR SEALING AT LEAST ONE PORTION OF AN ELECTRICAL DEVICE OR A CIRCUIT BOARD HERMETICALLY

(75) Inventor: Jason Shiue, Taipei (TW)

Correspondence Address: PATTERSON, THUENTE, SKAAR & CHRISTENSEN, P.A., 4800 IDS CENTER, 80 SOUTH 8TH STREET, MINNEAPOLIS, MN, 55402-2100, US

(73) Assignee: QBAS CO., LTD., Taipei (TW)

(21) Appl. No.: 12/168,609

(22) Filed: Jul. 7, 2008

(30) Foreign Application Priority Data
May 8, 2008 (TW) 097116979

(51) Int. Cl. H05K 5/06; B32B 37/06

(52) U.S. Cl. 174/50.51; 156/275.5

(57) ABSTRACT

An electrical device is provided. The electrical device comprises a circuit board and a waterproof layer. The waterproof layer substantially seals at least one portion of the circuit board to prevent the short circuit after water infiltrating. Thereby, this particular structure provides superior waterproof protection for the electrical device. This electrical device may be installed in a band structure which facilitates portability. Moreover, the present invention further provides methods for sealing at least one portion of the electrical device or the circuit board hermetically, while the electrical device or the circuit board would be sealed with the waterproof layer hermetically.

This application claims priority to Taiwan Patent Application No. 097116979 filed on May 8, 2008, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention provides an electrical device that is waterproof. In particular, the electrical device is adapted for use in a moist environment or in sports such as aquatics, swimming or diving.

2. Descriptions of the Related Art

With the continuous development of living standards, modern people have imposed increasingly heightened requirements on maintaining physical fitness and improving the quality of life. During activities that involve repeated actions or monotonic environments, such as jogging or cycling, people have used MP3 players to enhance the enjoyment of the physical activity. Over recent years, such players are used in underwater sports such as swimming and diving. However, it is important that these electrical devices be waterproof so that they do not short-circuit.

Presently, a waterproofing solution most commonly used for electrical devices is as follows. A waterproof enclosure is used to cover the electrical device with a sealing method such as waterproof gaskets, waterproof rubber strips or ultrasonic welding at the seams of the waterproof enclosure to prevent water from leaking into the electrical device. The waterproof enclosures may be categorized into either specific or common for electrical devices. The specific design has high design costs and fails to accommodate the ever-changing profiles of modern electrical devices. On the other hand, common design for electrical devices is not aesthetic, bulky and heavy. Meanwhile, after being opened and closed a large number of times, the waterproof enclosures will experience abrasion, causing gaps and aging, both of which may lead to loss of waterproof functionality. Furthermore, even though some electrical devices with a waterproof gasket are disposed directly on the waterproof enclosures gradually provided, not all electrical devices may adapt this method of waterproofing, and shall be purchased additionally by a user. Moreover, such an electrical device also entails the use of particular structures and materials, which leads to a high cost.

To apply the aforesaid waterproofing techniques to a diving environment, a special design of structures and particular materials will be further needed to prevent the rupture and deformation of the enclosure due to a high water pressure, which represents an increase in costs. In view of this, it is important to provide a waterproofing solution for electrical devices that is highly reliable, simple in structure and manufacturing process, cheap in costs, and adapted for various electrical devices while still maintaining the light weight, slimness and aesthetics.

### SUMMARY OF THE INVENTION

One objective of this invention is to provide an electrical device that is waterproof. Accordingly, the electrical device can be used in aquatics or underwater sports without failure due to damp, water sputtering, raining or the like. For this purpose, the electrical device comprises a circuit board and a waterproof layer. The waterproof layer is substantially sealed onto at least one portion of the circuit board. In this way, the waterproof layer is able to prevent water from contacting the electronic components of the circuit board, thus preventing short circuit. Accordingly, this electrical device can be further used in hair bands, diving goggles or other band-like structures to enhance the applicability. The waterproof layer does not only cover the circuit board, but may directly cover the surface of the electrical device and provide water protection.

Another objective of this invention is to provide a method for sealing at least one portion of an electrical device with a waterproof layer. According to this method, a non-solid adhesive is applied onto the at least one portion of a surface of the electrical device by dipping, spraying, pouring or brushing. Then, by curing the non-solid adhesive, the semi-cured film or cured film is formed on the surface of the electrical device to prevent water from leaking into the device. This method also involves that the waterproof layer is sealed on at least one portion of a circuit board of the electrical device to make the circuit board waterproof itself.

Yet another objective of this invention is to provide a method for sealing at least one portion of a circuit board with a waterproof layer. According to this method, a film is applied onto the at least one portion of the surface of the circuit board, and is then heated to be closely attached onto the surface, to provide waterproof protection.

Yet a further objective of this invention is to provide a method for sealing at least one portion of a circuit board with a waterproof layer. According to this method, the circuit board is enclosed by applying an elastically shrinkable bag onto a surface thereof, wherein the elastically shrinkable bag has at least one open end through which the circuit board is put into the bag. Then, the at least one open end is sealed to provide a waterproof effect.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is an exploded view of an electrical device in accordance with an embodiment of this invention;

FIG. 2 is an assembled view of an electrical device in accordance with an embodiment of this invention;

FIG. 3 is a schematic view of an electrical device in accordance with another embodiment of this invention;

FIG. 4 is a schematic view of a band-like structure in accordance with a further embodiment of this invention;

FIG. 5 is a flow diagram of a method for sealing a waterproof layer onto the surface of a circuit board in an electrical device of this invention;

FIG. 6 is a flow diagram of another method for sealing a waterproof layer onto the surface of a circuit board in an electrical device of this invention; and

FIG. 7 is a flow diagram of yet another method for sealing a waterproof layer onto the surface of a circuit board in an electrical device of this invention.

### DESCRIPTION OF THE PREFERRED EMBODIMENT

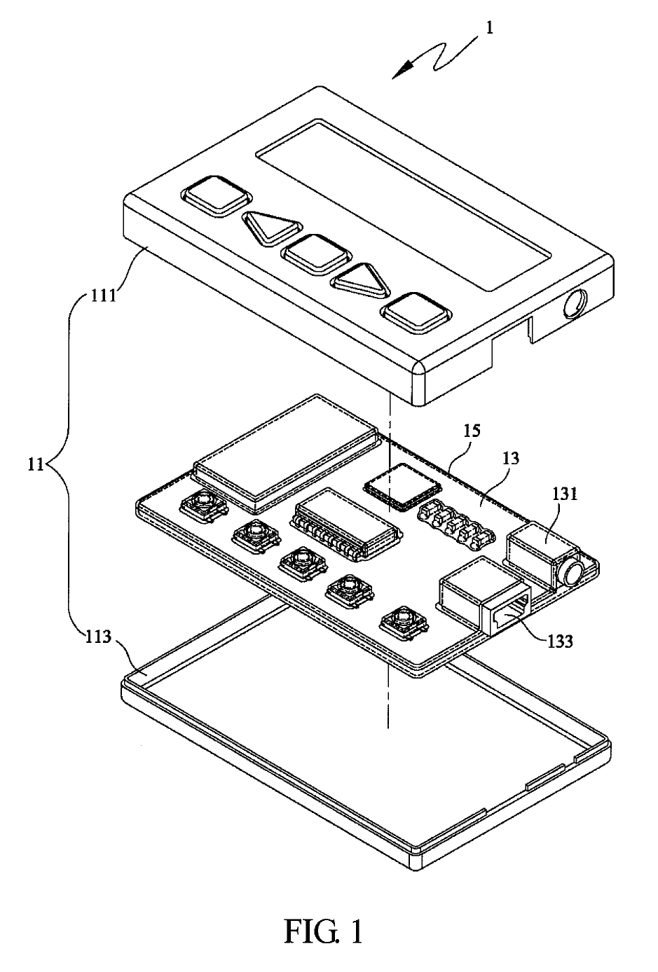

An embodiment of this invention is an electrical device 1. In this embodiment, the electrical device 1 is an MP3 music player. As depicted by the exploded view of FIG. 1, the electrical device 1 comprises a casing 11, a circuit board 13 and a waterproof layer 15.

The casing 11 comprises an upper casing 111 and a lower casing 113, which are adapted to define a space to receive the circuit board 13. In other embodiments, the casing may be eliminated or replaced by other elements. For example, the casing 11 of this embodiment may be replaced by any members defined with a space adapted to receive the circuit board 13 therein.

In this embodiment, the circuit board 13 has an earphone socket 131 and a data transmission socket 133 disposed at the edge thereof for connection with an earphone and data transmission lines to allow the user to listen to music or transmit data. The circuit board 13 used in this embodiment is a rectangular dual-layer printed circuit board (PCB), with only some of electronic components thereof depicted diagrammatically in this figure. However, substitutions and modifications may be made thereto by those skilled in the art. For example, the circuit board may be of other forms (e.g., a multi-layer PCB), in other shapes, or formed by a plurality of circuit boards in combination.

The waterproof layer 15 is substantially sealed onto at least one portion of the circuit board 13 to form the protection film for isolating water. In practical applications, the waterproof layer 15 may be a silicon rubber film, a cling film, an elastically shrinkable film or a heat-shrinkable film, and may be made of a material selected from a group consisting of (but not limited to) the chemical-setting resin, UV-setting resin and thermal-setting resin, or selected from a group consisting of silicon rubber, natural rubber, thermo plastic rubber, plastic elastomer, plastic urethane, polypropylene or a liquid adhesive. In this embodiment, the waterproof layer 15 is made of the silicon rubber.

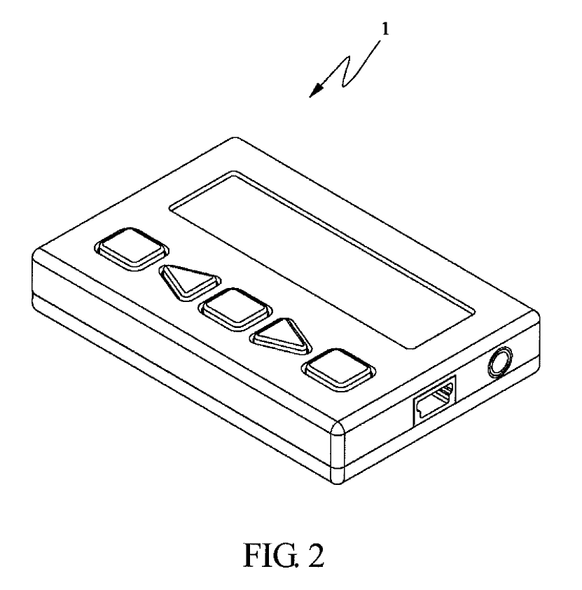

Due to the isolating effect of the waterproof layer 15, the circuit board 13 will not short-circuit when coming into contact with water. As a result, the electrical device 1 is waterproof regardless of whether the circuit board 13 of the electrical device 1 is accommodated in a casing 11. In this embodiment, the waterproof layer 15 covers most of the circuit board 13. Although in other embodiments, the waterproof layer 15 may cover only a portion of the circuit board 13 so long as it can prevent short circuit between particular electronic components. As shown in the assembled view of FIG. 2, the electrical device 1 that is covered with the waterproof layer 15 has an appearance which makes no difference from that of the same electrical device not covered with the waterproof layer 15.

In other embodiments, a metallic powder may be added in the material of the waterproof layer 15 to improve the thermal conductivity thereof. Optionally, the electrical device 1 may also include a thermal dissipating device. The thermal dissipating device is adapted to come into direct contact with the waterproof layer 15 and be disposed on the circuit board 13 to facilitate thermal dissipation from at least one electronic component of the circuit board 13. It should be emphasized that the above structure is only described for illustration purposes, rather than to limit this invention. In other embodiments, the electrical device may also be a watch, a counter, a depth gauge, an ascent speed indicator, a flashlight, a keyboard, an electrical appliance (e.g., a hair drier, a remote controller and etc.), a phone, a handheld mobile device or other electrical devices. Furthermore, the handheld mobile device may be a cellular phone, a personal digital assistant (PDA) or a global positioning system (GPS). Therefore, those skilled in the art may provide different designs depending on different requirements.

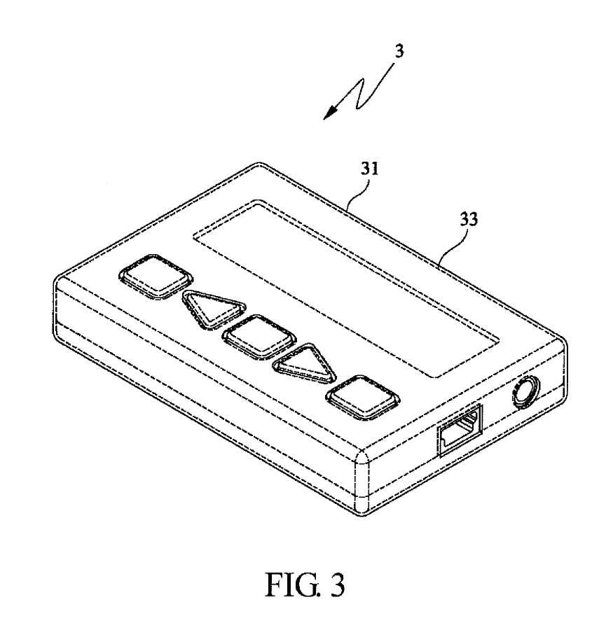

This invention is not limited to have the waterproof layer covered on the circuit board. In other words, the waterproof layer may also be covered on the electrical device to form a waterproof electrical device, as shown in FIG. 3. For example, in an MP3 player, the electrical device 3 comprises a waterproof layer 31 and a body 33 which further comprises at least one electronic component (not shown). The body 33 has a surface, on which the waterproof layer 31 is covered in close contact therewith to provide waterproof protection.

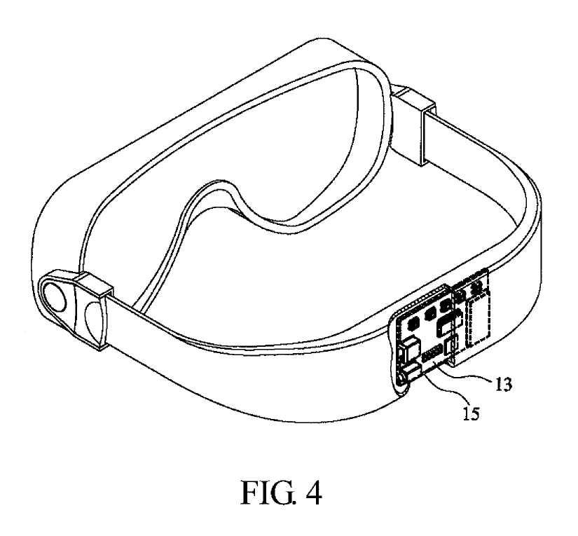

Additionally, the casing 11 of the electrical device 1 may be eliminated and instead, the circuit board 13 covered with the waterproof layer 15 is embedded into a band-like structure. In this embodiment, the band-like structure 4 is a band of a diving goggle as shown in FIG. 4, and the electrical device 1 is still an MP3 music player. However, in other embodiments, the band-like structure may also be a band of a swimming goggle, an arm band, a leg band, a waistband, a hair band or other band-like structures. In addition, a user can wear such diving goggles to listen to music without need of any other devices, thus reducing the burden of accessories.

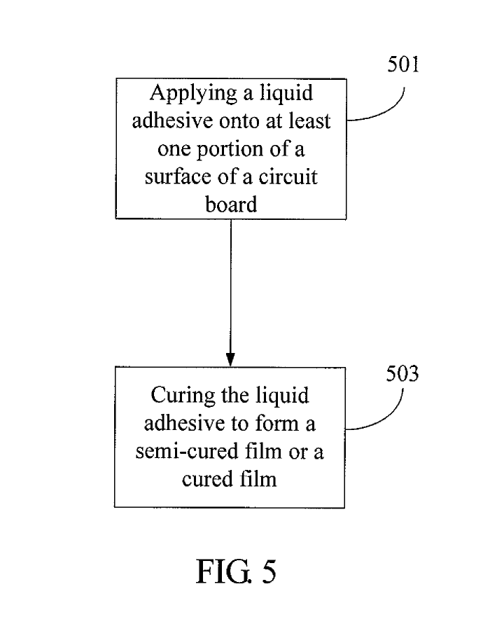

As shown in FIG. 5, a method for sealing at least one portion of an electrical device is depicted therein. Here, an example in which a circuit board 13 of the electrical device 1 of the previous embodiment is covered is described. In other embodiments, the electrical device 1 may be covered directly. In more detail, this method may be used to cover the circuit board 13 of the electrical device 1, cover the outer surface of the electrical device 1 directly, or even cover other electrical products or components.

Initially in step 501, a circuit board 13 is provided and a non-solid adhesive is applied onto at least one portion of the surface of the circuit board 13. More specifically, the portion of the surface represents an area which is subject to short-circuit when exposed to water. The non-solid adhesive may be a liquid adhesive or a semi-solid adhesive, and may be made of a material selected from a group consisting of silicon rubber, UV-setting resin and thermosetting resin. This applying step may be accomplished by dipping, spraying, pouring or brushing. It should be especially noted that an earphone plug and a data transmission line must be plugged in the earphone socket 131 and the data transmission socket 133 of the circuit board 13 respectively before applying the non-solid adhesive to prevent the non-solid adhesive from adhering to the inner surface of the sockets and causing signal degradation due to poor contact conditions.

Next in step 503, the non-solid adhesive is cured to form a semi-cured film or a cured film. This curing step may be accomplished through exposure to UV light irradiation, room temperature or high temperature baking. More specifically, the circuit board 13 applied with the non-solid adhesive is exposed at first to UV irradiation to cure the surface of the non-solid adhesive, and is then placed at room temperature to allow the non-solid adhesive to set or is subjected to high temperature baking process to speed up the curing process. To prevent damage to the electrical device 1 by high temperature baking, the temperature of the high temperature baking process is determined according to the maximum allowable temperature of electronic components and mechanical elements included in the electrical device 1. The maximum temperature of the baking process should be below 180□. Subsequent to the waterproof treatment described above, the circuit board 13 is disposed into the casing 11 as it was originally installed, thus obtaining an electrical device 1 with waterproof protection.

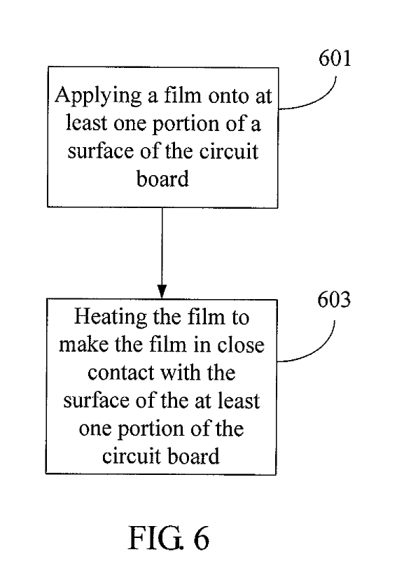

As shown in FIG. 6, there is a method for sealing at least one portion of the circuit board 13 with the waterproof layer 15 in the electrical device 1 of the previous embodiment. Initially in step 601, a circuit board 13 is provided, and a film is applied onto at least one portion of the surface of the circuit board 13. To be more specific, the film may be a silicon rubber film, a cling film or a heat-shrinkable film. It should be especially noted that an earphone plug and a data transmission line must be plugged in the earphone socket 131 and the data transmission socket 133 of the circuit board 13 respectively before applying the film to prevent the film from adhering to the inner surface of the sockets and causing signal degradation due to poor contact conditions.

Next in step 603, the film is heated to make the film come into close contact with the surface of the at least one portion of the circuit board. Subsequent to the waterproof treatment described above, the circuit board 13 is disposed into the casing 11 as it was originally installed, thus obtaining an electrical device 1 with a waterproof protection.

The electrical device 1 with a waterproof protection obtained by the aforesaid method is advantageous in that portions of the circuit board 13 that may suffer from short-circuiting when exposed to water are isolated directly. Secondly, in contrast to the conventional waterproof hard enclosure that is bulky and inconvenient to use, the waterproof layer 15 is formed inside a casing, which may be aesthetic and slim to fit the various electrical devices.

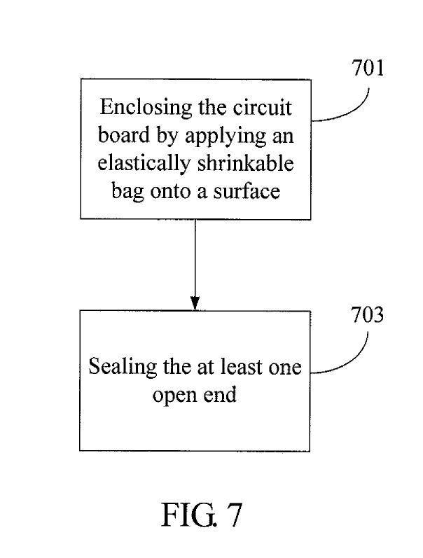

As shown in FIG. 7, there is another method for sealing at least one portion of the circuit board 13 with the waterproof layer 15 in the electrical device 1 of the previous embodiment. Initially in step 701, a circuit board 13 is provided and is enclosed by applying an elastically shrinkable bag onto the surface thereof. The elastically shrinkable bag has at least one open end and two holes for sockets. The circuit board 13 is put into the bag through the open end. Likewise, since the circuit board 13 comprises an earphone socket 131 and a data transmission socket 133, the two socket openings of the bag shall be aligned with these two plugs respectively to prevent the elastically shrinkable bag from covering the sockets.

Next in step 703, the at least one open end is sealed. The sealing step is performed by injecting an adhesive material to seal the at least one open end. Alternatively, the sealing step further heats the at least one open end so that portions of the elastically shrinkable bag around the at least one open end are closed together.

The electrical device of this invention is easy to manufacture, aesthetic, lightweight, slim, inexpensive and adapted for various kinds of electrical devices. Furthermore, the electrical device of this invention may not only be used in aquatic sports and sports that make people sweaty, but may operate properly in the rain or when sputtered with water. Therefore, provided with necessary accessories such as waterproof earphones or waterproof headphones, users can use various electrical devices under water or in a moist environment without having to worry about short circuit.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. An electrical device, comprising:
a circuit board; and
a waterproof layer substantially being sealed onto at least one portion of the circuit board.

2. The electrical device as claimed in claim 1, further comprising a casing, wherein the circuit board is disposed in the casing.

3. The electrical device as claimed in claim 1, wherein the electrical device is a multimedia player, a watch, a counter, a depth gauge, an ascent speed indicator, a flashlight, a keyboard, an electrical appliance or a handheld mobile device.

4. The electrical device as claimed in claim 3, wherein the handheld mobile device is selected from the group consisting of a cellular phone, a personal digital assistant (PDA), a global positioning system (OPS), and the combination thereof.

5. The electrical device as claimed in claim 1, wherein the waterproof layer is selected from the group of material consisting of chemical-setting resin, UV-setting resin and thermosetting resin.

6. The electrical device as claimed in claim 1, wherein the waterproof layer is selected from the group of material consisting of the silicon rubber, natural rubber, thermo plastic rubber, plastic elastomer, plastic urethane, polypropylene and liquid adhesive.

7. The electrical device as claimed in claim 1, wherein the waterproof layer is one of a silicon rubber film, a cling film, an elastically shrinkable film and a heat-shrinkable film.

8. An electrical device, comprising a waterproof layer and a body, wherein the body comprises at least one electronic component, and the body has a surface covered with the waterproof layer and the waterproof layer is in close contact with the surface.

9. A band structure, comprising the electrical device of claim 1.

10. A method for sealing at least one portion of an electrical device, the method comprising the steps of:
applying a non-solid adhesive onto the at least one portion of a surface of the electrical device; and
forming a semi-cured film or a cured film by curing the non-solid adhesive.

11. The method as claimed in claim 10, wherein the applying step is performed by applying the non-solid adhesive onto at lease one portion of the surface of a circuit board of the electrical device.

12. The method as claimed in claim 10, wherein the non-solid adhesive is liquid adhesive or semi-solid adhesive.

13. The method as claimed in claim 10, wherein the applying step is performed by applying the non-solid adhesive onto the at least one portion of the surface of the electrical device by dipping, spraying, pouring or brushing.

14. The method as claimed in claim 10, wherein the step of forming the cured or semi-cured film is performed by placing the electrical device applied with the non-solid adhesive at room temperature, under UV light irradiation or high temperature baking.

15. The method as claimed in claim 14, wherein the applying step is performed by applying the non-solid adhesive onto the at least one portion of the surface of a circuit board of the electrical device, and the curing step is performed by baking the circuit board applied with the non-solid adhesive below a temperature of 180□.

16. The method as claimed in claim 10, wherein the applying step is performed by applying the silicon rubber, UV-setting resin or thermosetting resin on the at least one portion of the surface of the electrical device.

17. A method for sealing at least one portion of a circuit board, comprising the steps of:
applying a film on the at least one portion of a surface of the circuit board; and
closely contacting the film with the surface by heating the film.

18. The method as claimed in claim 17, wherein the applying step is performed by applying a silicon rubber film, a cling film or a heat-shrinkable film on the at least one portion of the surface of the circuit board.

19. A method for sealing at least one portion of a circuit board, comprising the steps of:
enclosing the circuit board by applying an elastically shrinkable bag onto a surface thereof, wherein the elastically shrinkable bag has at least one open end, the circuit board is put into the bag through the open end; and
sealing the at least one open end.

20. The method as claimed in claim 19, wherein the sealing step is performed by injecting an adhesive material to seal the at least one open end.

21. The method as claimed in claim 20, wherein the sealing step further comprises the step of heating the at least one open end.
